(19) United States
(12) Patent Application Publication
(10) Pub. No.: US 2025/0081755 A1
(43) Pub. Date: Mar. 6, 2025

(54) DISPLAY PANEL AND ELECTRONIC TERMINAL

(71) Applicant: WUHAN CHINA STAR OPTOELECTRONICS TECHNOLOGY CO., LTD., Wuhan, Hubei (CN)

(72) Inventors: Fei AI, Wuhan, Hubei (CN); Dewei SONG, Wuhan, Hubei (CN); Chengzhi LUO, Wuhan, Hubei (CN)

(21) Appl. No.: 18/561,180

(22) PCT Filed: Jun. 30, 2023
(86) PCT No.: PCT/CN2023/104850

§ 371 Date: Nov. 15, 2023

(30) Foreign Application Priority Data
Sep. 7, 2022 (CN) 202211088401.8

(51) Int. Cl. H10K 59/123; H10K 59/121; H10K 59/124

(52) U.S. Cl. CPC H10K 59/123; H10K 59/1213; H10K 59/124

(57) ABSTRACT

A display panel and an electronic terminal are provided, including a substrate and a first thin film transistor (TFT) disposed on the substrate. The first TFT includes a first active portion, and a first source and a first drain which are arranged on two ends of the first active portion and electrically connected to the two ends. The display panel also includes a pixel electrode layer arranged on a first source-drain portion and electrically connected to the first drain. A material of the first drain includes a transparent conductive material.

### CROSS-REFERENCE TO RELATED APPLICATION

This application is a national phase application of International Application No. PCT/CN2023/104850, filed on Jun. 30, 2023, which claims the benefit of priority to Chinese Patent Application No. 202211088401.8 filed on Sep. 7, 2022, the content of which is incorporated herein by reference in its entirety.

### TECHNICAL FIELD

The present application relates to a field of display technology, and in particular to manufacturing of display devices, specifically to a display panel and an electronic terminal.

### DESCRIPTION OF RELATED ART

With the development of display technology, consumer electronics products such as mobile phones, televisions, personal digital assistants, digital cameras, laptops, desktop computers, virtual reality (VR), and augmented reality (AR) have emerged, all of which rely on display devices for their applications.

Among these, thin-film transistors (TFT) serve as the primary driving components in display devices and directly influence the development direction of high-performance flat-panel displays. However, display devices in the VR and AR fields require higher resolutions, leading to smaller sizes for each subpixel. The size of TFTs within each subpixel is difficult to reduce, resulting in a lower aperture ratio for subpixels.

As a result, there is an urgent need to improve the aperture ratio of subpixels in current VR and AR display devices.

### SUMMARY OF INVENTION

An objective of the present application is to provide a display panel and an electronic terminal to solve technical issues of low aperture ratios of sub-pixels in existing virtual reality (VR) and augmented reality (AR) display devices.

In order to solve the above technical issues, the present application provides a display panel, including a display part. The display panel includes:
a substrate;
a first thin film transistor (TFT) disposed on the substrate and including a first active portion, a first source, and a first drain, the first source and the first drain disposed on the first active portion, wherein the first source is electrically connected to a first end of the first active portion, and the first drain is electrically connected to a second end of the first active portion; and
a pixel electrode layer disposed on the first TFT and electrically connected to the first drain,
wherein a material of the first drain includes a transparent conductive material.

In one embodiment, the first TFT further includes a first gate disposed corresponding to the first active portion;
wherein the display panel further includes:
a first planarization layer disposed between the first drain and the pixel electrode layer and including a first opening, wherein the pixel electrode layer is connected to the first drain through the first opening;
wherein the first opening is positioned corresponding to the first gate.

In one embodiment, the display panel further includes:
an insulating layer disposed between the first source and the first drain which are arranged in different layers,
wherein a projection of the first source projected on the substrate at least partially overlaps with a projection of the first gate projected on the substrate.

In one embodiment, the first source is made of a material same as the material of the first drain, and the first source and the first drain are disposed in a same layer.

In one embodiment, the display panel further includes:
a passivation layer disposed on the pixel electrode layer, wherein a portion of the passivation layer, corresponding to the first opening, is provided with a second opening recessed downward;
a second planarization layer filled in the second opening, wherein an upper surface of the second planarization layer is flush with an upper surface of a portion of the passivation layer corresponding to the first planarization layer; and
a common electrode layer disposed on the passivation layer and the second planarization layer.

In one embodiment, the display panel further includes:
a second thin film transistor (TFT) disposed on the substrate and including a second gate and a second active portion which are disposed in different layers and arranged corresponding to each other;
wherein the second TFT is electrically connected to the first TFT, a material of the first active portion of the first TFT comprises metal oxide, and a material of the second active portion of the second TFT includes low-temperature polysilicon.

In one embodiment, the display panel further includes:
a first light-shielding layer disposed between the substrate and the first active portion, wherein the first light-shielding layer is disposed corresponding to the first active portion and arranged in a same layer as the second gate.

In one embodiment, the display panel further includes:
a second light-shielding layer including a first light-shielding portion and a second light-shielding portion disposed in a same layer;
wherein the first light-shielding portion is disposed corresponding to the first active portion and arranged between the substrate and the first TFT; and
wherein the second light-shielding portion is disposed corresponding to the second active portion and arranged between the substrate and the second TFT.

In one embodiment, the second TFT further includes a second source and a second drain which are arranged in a same layer;
the display panel further includes:
a buffer layer disposed on the substrate, wherein the second gate is disposed on the buffer layer;
a third gate insulating layer disposed on the second gate and the buffer layer, wherein the second gate and the first light-shielding layer are disposed on the third gate insulating layer;
a second gate insulating layer disposed on the second gate, the first light-shielding layer, and the third gate insulating layer, wherein the first active portion is disposed on the second gate insulating layer;
a first gate insulating layer disposed on the first active portion and the second gate insulating layer, wherein the first gate, the second source, and the second drain are disposed on the first gate insulating layer;
an interlayer insulating layer disposed on the first gate, the second source, the second drain, and the first gate insulating layer, wherein the first source is disposed on the interlayer insulating layer; and
an insulating layer disposed on the first source and the interlayer insulating layer, wherein the first drain is disposed on the insulating layer.

In one embodiment, the first gate of the first TFT is disposed on the first active portion, and the second gate of the second TFT is disposed on the second active portion.

In one embodiment, the display panel includes a display part and a non-display part disposed on at least one side of the display part,
wherein the first TFT is included in the display part, and the second TFT is included in the non-display part.

Embodiments of the present application provide an electronic terminal, including any display panel as described above.

### Beneficial Effects

The present application provides a display panel and an electronic terminal, including: a substrate; a first thin film transistor (TFT) located on the substrate, wherein the first TFT includes a first active portion, a first source, and a first drain, the first source and the first drain are located on the first active portion, the first source is electrically connected to a first end of the first active portion, and the first drain is electrically connected to a second end of the first active portion; and a pixel electrode layer located on the first TFT and electrically connected to the first drain, wherein a material of the first drain includes a transparent conductive material. Combining the high transparency of the first active portion and the pixel electrode layer, the material of the first drain in this application includes a transparent conductive material. Therefore, the first drain can also have a high level of transparency, preventing the first drain from blocking a significant amount of light in a vertical direction, thus increasing the aperture ratio of a corresponding subpixel.

### BRIEF DESCRIPTION OF DRAWINGS

The present application will be further described below through the accompanying drawings. It should be noted that the drawings in the following description are only used to explain some embodiments of the present application. Those skilled in the art can obtain other drawings based on these drawings without creative efforts.

FIG. 1 is a first schematic cross-sectional view of a display panel provided by one embodiment of the present application.

FIG. 2 is a second schematic cross-sectional view of the display panel provided by one embodiment of the present application.

FIG. 3 is a third schematic cross-sectional view of the display panel provided by one embodiment of the present application.

FIG. 4 is a fourth schematic cross-sectional view of the display panel provided by one embodiment of the present application.

### DETAILED DESCRIPTION OF EMBODIMENTS OF THE INVENTION

The technical solutions in the embodiments of the present application are clearly and completely described below with reference to the accompanying drawings in the embodiments of the present application. Obviously, the described embodiments are only some of the embodiments of the present application, but not all of the embodiments. Based on the embodiments in this application, all other embodiments obtained by those skilled in the art without making creative efforts fall within the scope of protection of this application.

In the description of this application, it should be understood that the orientation or positional relationship indicated by the terms “upper”, “lower”, “close”, “away”, “two ends”, etc. are based on the orientation or position relationship shown in the drawings. For example, “on” means that the surface is above the object. It can specifically refer to being directly above, being diagonally above, or being on the upper surface, as long as it is above the level of the object. “Two ends” refers to the two opposite positions of the object that can be reflected in the drawings, where the two positions can be in direct or indirect contact with the object. The above positions or positional relationships are only for the convenience of describing this application and simplifying the description. It is not intended to indicate or imply that the device or element referred to must have a specific orientation, be constructed and operated in a specific orientation, and therefore should not be construed as a limitation to the present application.

In addition, it should be noted that the accompanying drawings only provide structures and steps that are closely related to the application, and some details that are not closely related to the application are omitted. The purpose is to simplify the drawings and make the application points clear, rather than indicating that the actual devices and methods are identical to the drawings. This does not serve as a limitation on the actual devices and methods.

The present application provides a display panel, which includes but is not limited to the following embodiments and combinations between the following embodiments.

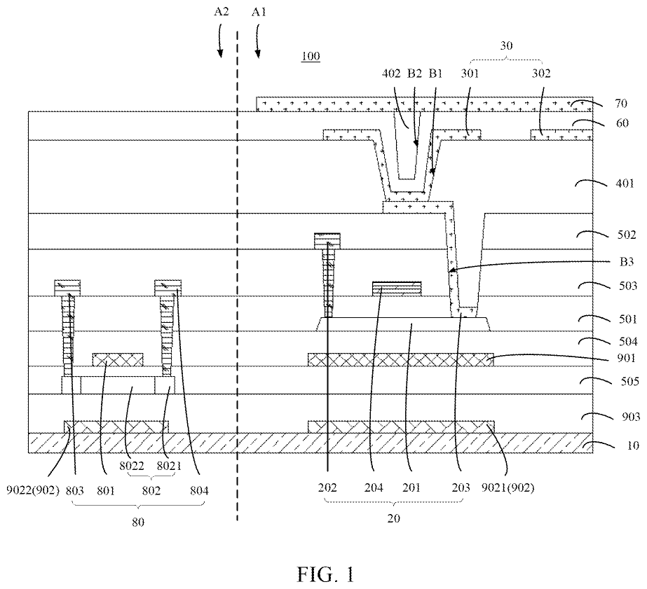

In one embodiment, as shown in FIGS. 1 to 4, the display panel 100 includes: a substrate 10; and a first thin film transistor (TFT) 20 disposed on the substrate 10. The first TFT 20 includes a first active portion 201 and a first source-drain portion disposed on the first active portion. A first source 202 of the first source-drain portion is electrically connected to a first end of the first active portion 201, and a first drain 203 of the first source-drain portion is electrically connected to a second end of the first active portion 201. A pixel electrode layer 30 is disposed on the first source-drain portion and electrically connected to the first drain 203, wherein a material of the first drain 203 includes a transparent conductive material.

The display panel 100 includes a display area A1 and a non-display area A2 disposed on at least one side of the display area A1. For example, the non-display area A2 can be arranged to at least partially surround a periphery of the display area A1. The display panel can be defined to include a display part disposed on the substrate 10 and constitutes the display area A1, and a non-display part disposed on the substrate 10 and constitutes the non-display area A2. That is to say, the first TFT 20 can be considered to be included in the display part. Specifically, the display area A1 can be provided with multiple sub-pixels and corresponding multiple pixel driving circuits for displaying images, and the non-display area A2 can be provided with driving units (such as gate driving circuits) for providing driving signals to the pixel driving circuits. Therefore, the first TFT 20 in the present embodiment arranged in the display area A1 can be understood as a device used to constitute the pixel driving circuit. Furthermore, a material of the first active portion 201 in the first TFT 20 can include metal oxide, so that the first TFT 20 has the advantages of good uniformity and low leakage current, which is beneficial to driving the sub-pixel.

The substrate 10 can be a rigid substrate or a flexible substrate. A material of the rigid substrate can include at least one of glass and quartz. A material of the flexible substrate can include polymer resin, such as polyimide. A material of the first source-drain portion can be a conductive material, so that the first source 202 has at least one of a corresponding voltage and current, and the first drain 203 has at least one of a corresponding voltage and current. Specifically, the display panel 100 may be a liquid crystal display panel or an organic light-emitting diode (OLED) display panel. For example, when the display panel 100 is a liquid crystal display panel or a bottom-emitting OLED display, the larger the size of a low light transmittance structure in the first TFT 20, the lower the aperture ratio of the corresponding sub-pixel.

It can be understood that in this embodiment, based on the first active portion 201 and the pixel electrode layer 30 having a high transmittance, the material of the first drain 203 includes a transparent conductive material, enabling the first drain 203 to have a higher transmittance. This helps to prevent the first drain 203 from blocking a significant amount of light in the vertical direction, thereby increasing the aperture ratio of the corresponding subpixel. The material of the first drain 203 can include indium tin oxide (ITO).

In one embodiment, as shown in FIGS. 1 to 4, the first TFT 20 further includes a first gate 204 disposed corresponding to the first active portion 201. The display panel 100 further includes a first planarization layer 401 disposed between the first drain 203 and the pixel electrode layer 30 and provided with a first opening B1. The pixel electrode layer 30 is connected to (specifically, making contact with) the first drain 203 through the first opening B1, wherein the first opening B1 is positioned corresponding to the first gate 204.

Specifically, this embodiment does not impose any restrictions on whether the first TFT 20 is a top-gate structure or a bottom-gate structure; it only needs to satisfy the condition that the first opening B1 is positioned corresponding to the first gate 204. Here, as an example for illustrative purposes, the first TFT 20 is a top-gate structure. For example, the display panel 100 can also include a first gate insulating layer 501 located between the first gate 204 and the first active portion 201. The first gate insulating layer 501 is used to insulate the first gate 204 from the first active portion 201. A material of the first gate insulating layer 501 can include at least one of a silicon compound and a metal oxide. For instance, the material of the first gate insulating layer 501 can include silicon oxide, silicon nitride, silicon oxynitride, aluminum oxide, tantalum oxide, hafnium oxide, zirconium oxide, or titanium oxide.

Specifically, in this embodiment, even though the first drain 203 and the pixel electrode layer 30 can be made from the same material, considering the greater thickness of the planarization layer 401 and the presence of at least the first gate insulating layer 501 and the first active portion 201 between the first drain 203 and the first active portion 201, which means a larger distance between the pixel electrode layer 30 and the first active portion 201, using a via technique would require filling material into deeper vias, increasing a risk of material discontinuity. However, in this application, the first drain 203 and the pixel electrode layer 30 are separately provided. Further, the first drain 203 is electrically connected to the first active portion 201, and the pixel electrode layer 30 is formed in the first opening B1 to make contact and electrical connection with the first drain 203. This enhances the reliability of the electrical connection between the pixel electrode layer 30 and the first active portion 201.

It's worth noting that, considering the need for high conductivity, the first gate 204 can be constituted using low-resistance materials. A material of the first gate 204 can include at least one of the following: molybdenum, aluminum, platinum, palladium, silver, magnesium, gold, nickel, neodymium, iridium, chromium, calcium, titanium, tantalum, tungsten, or copper. Since metal materials have high reflectivity, a light transmittance of the first gate 204 is considered to be low, which occupies an aperture area of the corresponding subpixel. Additionally, due to the presence of the first opening B1 and the difference in materials between the planarization layer 401 and the pixel electrode layer 30 located within the first opening B1, a light transmittance at a location of the first opening B is also relatively low.

It can be understood that in this embodiment, the first opening B1 is positioned corresponding to the low-transmittance first gate 204. In other words, a projection of the first opening B1 projected on the substrate 10 and a projection of the first gate 204 projected on the substrate 10 can overlap. This design prevents the complete occupation of an independent area by the projection of the first opening B1 projected on the substrate 10, thereby avoiding excessive occupation of the aperture area of the corresponding subpixel. This further enhances the aperture ratio of the corresponding subpixel. Specifically, the projection of the first opening B1 projected on the substrate 10 can completely cover the projection of the first gate 204 on the substrate 10, or the projection of the first gate 204 projected on the substrate 10 can completely cover the projection of the first opening B1 projected on the substrate 10.

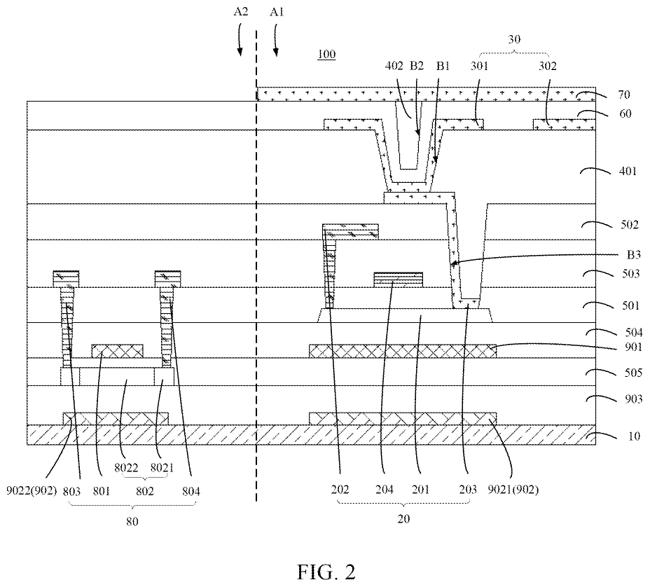

In one embodiment, as shown in FIGS. 1, 2 and 4, the display panel 100 further includes: an insulating layer 502 located between the first source 202 and the first drain 203 which are arranged in different layers. As shown in FIG. 2, a projection of the first source 202 projected on the substrate 10 at least partially overlaps the projection of the first gate 204 projected on the substrate 10. A material of the first source 202 can include metal to have lower impedance and higher conductivity. That is to say, a light transmittance of the first source 202 is low. The first source 202 and the first drain 203, made of different materials and positioned in different layers, are electrically insulated through the insulating layer 502.

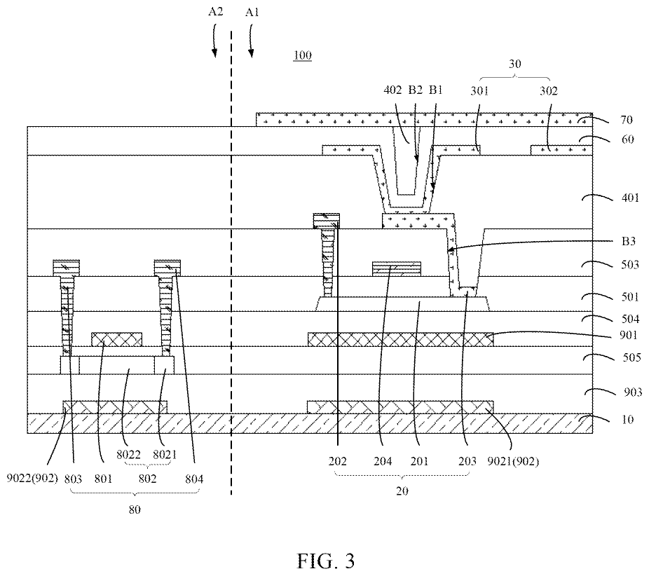

Furthermore, an interlayer insulating layer 503 can be placed between the first gate 204 and the first source 202 to insulate these two components. A material of the interlayer insulating layer 503 and a material of the insulating layer 502 can be referenced from the previous description regarding the material of the first gate 204. Moreover, based on the preceding discussion, it is evident that the first source 202 is electrically connected to the first end of the first active portion 201. For example, as shown in FIGS. 1 and 2, the display panel 100 also includes a third opening B3, which extends downward from an upper surface of the insulating layer 502 corresponding to the first end of the first active portion 201 to the first end of the first active portion 201. The first source 202 can extend from the insulating layer 502 to a bottom of the third opening B3 and make contact with the first end of the first active portion 201. Alternatively, as shown in FIG. 3, in the absence of the insulating layer 502, the third opening B3 can extend downward from a portion of an upper surface of the interlayer insulating layer 503, corresponding to the first end of the first active portion 201, to an upper surface of the first end of the first active portion 201.

It can be understood that, similarly, in this embodiment, the first source 202 with lower light transmittance is arranged corresponding to the first gate 204 with lower light transmittance. That is to say, a projection of the first source 202 projected on the substrate 10 overlaps with the projection of the first gate 204 projected on the substrate 10. This design avoids the complete occupation of an independent area by the projection of the first source 202 projected on the substrate 10, thus preventing excessive occupation of the aperture area of the corresponding subpixel. For example, this can prevent the extension of the first source 202 in a direction away from the first active portion 201, further improving the aperture ratio of the corresponding subpixel.

In one embodiment, as shown in FIG. 3, the material of the first source 202 is the same as the material of the first drain 203, and the first source 202 and the first drain 203 are positioned in the same layer. Specifically, as discussed earlier, in this embodiment, both the first source 202 and the first drain 203 can be made from the same material, which includes transparent conductive material (e.g., indium tin oxide). On one hand, this embodiment allows both the first source 202 and the first drain 203 to be manufactured in the same layer using the same process, enhancing the production efficiency of the display panel 100. On the other hand, since both the first source 202 and the first drain 203 have high light transmittance, even if their projections on the substrate 10 do not overlap, this configuration still reduces the sacrifice of the aperture ratio for the subpixels, enabling the subpixels to have a higher aperture ratio.

In one embodiment, as shown in FIGS. 1 to 4, the display panel 100 further includes: a passivation layer 60 located on the pixel electrode layer 30. A portion of the passivation layer 60, corresponding to the first opening B1, is recessed downward to form a second opening B2. A second planarization layer 402 completely fills the second opening B2, so that an upper surface of the second planarization layer 402 is flush with an upper surface of a portion of the passivation layer 60 corresponding to the first planarization layer 401. A common electrode layer 70 is located on the passivation layer 60 and the second planarization layer 402 and is disposed corresponding to the pixel electrode layer 30.

Specifically, in this embodiment, the display panel 100 can be understood as a liquid crystal display panel. The pixel electrode layer 30 may include a first pixel electrode portion 301 located in the first opening B1 and making contact with the first drain 203, as well as a second pixel electrode portion 302 separated from the first pixel electrode portion 301. For instance, the pixel electrode layer 30 can have a patterned design, where the second pixel electrode portion 302 and the first pixel electrode portion 301 can be electrically connected through other portions of the pixel electrode layer 30 to have a same pixel voltage. The patterned pixel electrode layer 30 and the common electrode layer 70 can form a storage capacitor, and a size of the storage capacitor is determined by a distance and an opposing area between the pixel electrode layer 30 and the common electrode layer 70.

It can be understood that in this embodiment, placing the common electrode layer 70 on one side of the pixel electrode layer 30 away from the substrate 10 has the following effects. On one hand, compared to positioning the common electrode layer 70 on the same layer as the first drain 203 made of transparent conductive material, this embodiment allows for the formation of a continuous common electrode layer 70, increasing the opposing area between the pixel electrode layer 30 and the common electrode layer 70. This, in turn, enhances the capacitance of the storage capacitor. On the other hand, due to a significantly smaller thickness of the passivation layer 60 compared to the first planarization layer 401, there is a smaller distance between the common electrode layer 70 and the pixel electrode layer 30. This smaller distance also contributes to an increased capacitance of the storage capacitor. In addition, in this embodiment, the second planarization layer 402 completely fills the second opening B2, reducing differences in the electric field direction at different positions between the common electrode layer 70 and the pixel electrode layer 30. This arrangement also helps mitigate thickness variations in the common electrode layer 70 at different positions caused by the presence of the second opening B2.

In one embodiment, as shown in FIGS. 1 to 4, the display panel 100 further includes a second TFT 80 located on the substrate 10. The second TFT 80 includes a second gate 801 and a second active portion 802, positioned in different layers and opposite to each other. The display panel 100 includes: the above-mentioned pixel driving circuit, as discussed above, that includes the first TFT 20, wherein the material of the first active portion 201 in the first TFT 20 includes metal oxide; and the above-mentioned gate driving circuit, electrically connected to the pixel driving circuit and including the second TFT 80, wherein a material of the second active portion 802 in the second TFT 80 includes low temperature polysilicon. The second TFT 80 can be located in the non-display area A2 (that is, included in the non-display part).

Specifically, the gate driving circuit of each stage can be electrically connected through a corresponding gate line to multiple pixel driving circuits, controlling the activation of the driving transistors (including the first TFT 20) in these pixel driving circuits. Furthermore, each pixel driving circuit can also be electrically connected to a corresponding data line, allowing the respective subpixel to be loaded with the appropriate voltage or current to emit corresponding light. It can be understood that in this embodiment, the use of materials, including low-temperature polysilicon, in the fabrication of the second active portion 802 of the second TFT 80, offers advantages such as high mobility, smaller size, fast charging, and rapid switching speed. The second active portion 802 can include doped portions 8021 at two ends and a channel portion 8022 located between these doped portions 8021. Doping materials like nitrogen or phosphorus may be used, and the channel portion 8022 may consist of polycrystalline silicon.

In one embodiment, as shown in FIGS. 1 to 4, the display panel 100 further includes a first light-shielding layer 901 positioned between the substrate 10 and the first active portion 201. The first light-shielding layer 901 is positioned corresponding to the first active portion 201 and is in the same layer as the second gate 801. Specifically, in this embodiment, the display panel 100 is a liquid crystal display panel as an example for illustration, it can be considered that the display panel 100 also includes a backlight layer on one side of the substrate 10 away from the TFTs. The light emitted by the backlight layer illuminates the TFTs. The first light-shielding layer 901 in this embodiment is positioned on one side of the first active portion 201 close to the backlight layer, and serves to block light that would otherwise be directed towards the first active portion 201. This helps reduce the photo-generated leakage current in the first TFT 20, thus enhancing the reliability of operations of the first TFT 20. Furthermore, the first light-shielding layer 901 is in the same layer as the second gate 801. Moreover, both the first light-shielding layer 901 and the second gate 801 can be made from the same material using the same manufacturing process, thereby improving the efficiency of producing the display panel 100.

Further, as shown in FIGS. 1 to 4, the display panel 100 can further include a second gate insulating layer 504 located between the second gate 801 and the first active portion 201. The second gate insulating layer 504 covers the second gate 801 and the first light-shielding layer 901 to electrically insulate the second gate 801, a layer where the first light-shielding layer 901 is located, and a layer where the first active portion 201 is located. A third gate insulating layer 505 is disposed between the second active portion 802 and the second gate 801. The third gate insulating layer 505 covers the second active portion 802 to electrically insulate a layer where the second active portion 802 is located and a layer where the second gate 801 is located. A material of the third gate insulating layer 505 and a material of the second gate insulating layer 504 can be referenced from the earlier description regarding the first gate insulating layer 501. Furthermore, the second TFT 80 can also include a second source-drain portion which is positioned in the same layer as the first gate 204. The second source-drain portion includes a second source 803 and a second drain 804. All three components—the first gate 204, the second source 803, and the second drain 804—can be made from the same material using the same manufacturing process, thus improving the efficiency of producing the display panel 100.

In one embodiment, as shown in FIGS. 1 to 3, the display panel 100 further includes: a second light-shielding layer 902 which includes a first light-shielding portion 9021 and a second light-shielding portion 9022 arranged in a same layer. The first light-shielding portion 9021 is arranged corresponding to the first active portion 201 and is located between the substrate 10 and the first TFT 20. The second light-shielding portion 9022 is arranged opposite to the second active portion 802 and is located between the substrate 10 and the second TFT 80. A buffer layer 903 can be provided between the second light-shielding layer 902 and the third gate insulating layer 505. The buffer layer 903 can consist of a single-layer film of insulating material such as silicon nitride and silicon oxide, or the buffer layer 903 can be a multilayer film with stacked layers of silicon nitride and silicon oxide. The buffer layer 903 is used to prevent the infiltration of unnecessary components such as impurities or moisture.

Specifically, the first light-shielding portion 9021 and the second light-shielding portion 9022, which are positioned in the same layer, can be made from the same material using the same manufacturing process, thus improving the efficiency of producing the display panel 100. Compared with only providing the first light-shielding layer 901, the second light-shielding layer 902 in this embodiment not only provides light shielding for the first active portion 201, but also provides light shielding for the second active portion 802. Certainly, it is possible to only set the second light-shielding layer 902 without the first light-shielding layer 901, and still achieve light-shielding for both the first active portion 201 and the second active portion 802. Based on this, for further process simplification, the second gate 801 and the first gate 204 can be made from the same material simultaneously, while other relevant film layers can be set according to actual requirements.

In one embodiment, as shown in FIGS. 1 to 3, the first gate 204 of the first TFT 20 is positioned above the first active portion 201, and the second gate 801 of the second TFT 80 is positioned above the second active portion 802. It can be understood that both the first TFT 20 and the second TFT 80 in this embodiment have a top-gate structure. For a liquid crystal display panel, the non-light-transmitting first gate 204 and second gate 801 are positioned further away from the backlight layer, which reduces the amount of light blockage, thereby improving the light transmittance of the display panel 100. For a top-emitting organic OLED display panel, the high-reflectance first gate 204 and second gate 801 are positioned closer to a light-emitting layer on the pixel electrode layer 30, allowing the first gate 204 and the second gate 801 to reflect more of the light emitted by the light-emitting layer and enhancing the utilization of light.

Specifically, the display panel in FIGS. 1 and 2 can be formed through the following steps:
S01: forming a second light-shielding layer on a substrate;
S02: forming a buffer layer on the substrate and the second light-shielding layer, forming a second active portion on the buffer layer, and forming a third gate insulating layer on the second active portion and the buffer layer;
S03: forming a second gate and a first light-shielding layer that are arranged in a same layer on the third gate insulating layer, and forming a second gate insulating layer on the third gate insulating layer, the second gate, and the first light-shielding layer;
S04: forming a first active portion on the second gate insulating layer;
S05: forming a first gate insulating layer on the first active portion and the second gate insulating layer, and forming an opening extending from an upper surface of a portion of the first gate insulating layer corresponding to an end of the first active portion and extending to an upper surface of the end of the first active portion, and forming two openings extending from upper surfaces of two portions of the first gate insulating layer corresponding to two ends of the second active portion and extending to upper surfaces of the two ends of the second active portion;
S06: forming a first gate and a second source-drain portion arranged in a same layer on the first gate insulating layer, and filling a second source and a second drain of the second source-drain portion to the corresponding two openings to contact the two ends of the second active portion;
S07: forming an interlayer insulating layer on the first gate insulating layer, the first gate, and the second source-drain portion, and forming two openings extending from upper surfaces of two portions of the interlayer insulating layer corresponding to two ends of the first active portion and extending to upper surfaces to the two ends of the first active portion;
S08: forming a first source in the interlayer insulating layer, and filling the first source into the corresponding opening to contact one end of the first active portion;
S09: forming an insulating layer on the interlayer insulating layer and the first source, and forming a via hole in a portion of the insulating layer that does not correspond to the first source but corresponds to the end of the second active portion, and forming a first drain in a portion of the insulating layer close to the via hole, wherein the first drain extends through the via hole and the corresponding opening to the corresponding end of the second active portion;
S10: forming a first planarization layer on the first drain and the insulating layer, wherein the first planarization layer also fills the via hole and the corresponding opening, and forming a via hole in a portion of the first planarization layer corresponding to the first gate;
S11: forming a pixel electrode layer on the first planarization layer, wherein the pixel electrode layer also extends to the via hole in the first planarization layer to contact the first drain;
S12: forming a passivation layer on the pixel electrode layer and the first planarization layer, wherein the passivation layer forms a recessed portion at a portion of the pixel electrode layer located in the via hole;
S13: forming a second planarization layer in the recessed portion to be flush with a portion of the passivation layer that is different from the recessed portion; and
S14: forming a common electrode layer on the passivation layer and the second planarization layer.

The structure of each film layer can refer to the relevant description above.

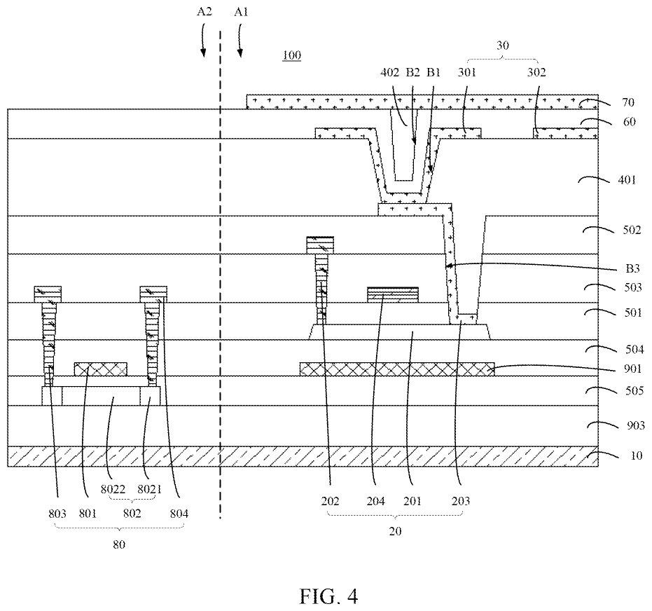

Specifically, compared with the display panel in FIG. 1, the display panel in FIG. 4 can be understood as omitting the above-mentioned step S01. In other words, the buffer layer can be directly formed on the substrate. For other steps, reference can be made to the related steps mentioned above.

The present application provides an electronic terminal, which includes but is not limited to any of the display panels mentioned above.

The present application provides a display panel and an electronic terminal, including a display part. The present application includes: a substrate, a first thin film transistor (TFT) located on the substrate. The first TFT includes a first active portion, a first source, and a first drain. The first source and the first drain are located on the first active portion. The first source is electrically connected to a first end of the first active portion, and the first drain is electrically connected to a second end of the first active portion. A pixel electrode layer is located on the first TFT and electrically connected to the first drain, wherein a material of the first drain includes a transparent conductive material. Combining the high transparency of the first active portion and the pixel electrode layer, the material of the first drain in this application includes a transparent conductive material. Therefore, the first drain can also have a high level of transparency, preventing the first drain from blocking a significant amount of light in a vertical direction, thus increasing the aperture ratio of a corresponding subpixel.

The structures of the display panel and the electronic terminal provided by the embodiments of the present application have been introduced in detail above. Specific examples are used in this article to illustrate the principles and implementation methods of the present application. The description of the above embodiments is only used to help understand the present application. technical solutions and their core ideas. Those of ordinary skill in the art should understand: It is still possible to modify the technical solutions recorded in the foregoing embodiments, or to equivalently replace some of the technical features. However, these modifications or substitutions do not cause the essence of the corresponding technical solutions to depart from the scope of the technical solutions of the embodiments of the present application.

1. A display panel, comprising:
a substrate;
a first thin film transistor (TFT) disposed on the substrate and comprising a first active portion, a first source, and a first drain, the first source and the first drain disposed on the first active portion, wherein the first source is electrically connected to a first end of the first active portion, and the first drain is electrically connected to a second end of the first active portion; and
a pixel electrode layer disposed on the first TFT and electrically connected to the first drain;
wherein a material of the first drain comprises a transparent conductive material;
wherein the first TFT further comprises a first gate disposed corresponding to the first active portion;
wherein the display panel further comprises:
a first planarization layer disposed between the first drain and the pixel electrode layer and comprising a first opening, wherein the pixel electrode layer is connected to the first drain through the first opening,
wherein the first opening is arranged corresponding to the first gate, and
wherein the first source is made of a material same as the material of the first drain, and the first source and the first drain are disposed in a same layer.

2. The display panel according to claim 1, further comprising:
an insulating layer disposed between the first source and the first drain which are arranged in different layers,
wherein a projection of the first source projected on the substrate at least partially overlaps with a projection of the first gate projected on the substrate.

3. The display panel according to claim 1, further comprising:
a passivation layer disposed on the pixel electrode layer, wherein a portion of the passivation layer, corresponding to the first opening, is provided with a second opening recessed downward;
a second planarization layer filled in the second opening, wherein an upper surface of the second planarization layer is flush with an upper surface of a portion of the passivation layer corresponding to the first planarization layer; and
a common electrode layer disposed on the passivation layer and the second planarization layer.

4. The display panel according to claim 1, further comprising:
a second thin film transistor (TFT) disposed on the substrate and comprising a second gate and a second active portion which are disposed in different layers and arranged corresponding to each other,
wherein the second TFT is electrically connected to the first TFT, a material of the first active portion of the first TFT comprises metal oxide, and a material of the second active portion of the second TFT comprises low-temperature polysilicon.

5. The display panel according to claim 4, further comprising:
a first light-shielding layer disposed between the substrate and the first active portion, wherein the first light-shielding layer is disposed corresponding to the first active portion and arranged in a same layer as the second gate.

6. The display panel according to claim 4, further comprising:
a second light-shielding layer comprising a first light-shielding portion and a second light-shielding portion disposed in a same layer,
wherein the first light-shielding portion is disposed corresponding to the first active portion and arranged between the substrate and the first TFT, and
wherein the second light-shielding portion is disposed corresponding to the second active portion and arranged between the substrate and the second TFT.

7. The display panel according to claim 5, wherein the second TFT further comprises a second source and a second drain arranged in a same layer;
the display panel further comprising:
a buffer layer disposed on the substrate, wherein the second gate is disposed on the buffer layer;
a first gate insulating layer disposed on the first active portion and the second gate insulating layer, wherein the first gate, the second source, and the second drain are disposed on the first gate insulating layer;
a second gate insulating layer disposed on the second gate, the first light-shielding layer, and the third gate insulating layer, wherein the first active portion is disposed on the second gate insulating layer;
a third gate insulating layer disposed on the second gate and the buffer layer, wherein the second gate and the first light-shielding layer are disposed on the third gate insulating layer;
an interlayer insulating layer disposed on the first gate, the second source, the second drain, and the first gate insulating layer, wherein the first source is disposed on the interlayer insulating layer; and
an insulating layer disposed on the first source and the interlayer insulating layer, wherein the first drain is disposed on the insulating layer.

8. The display panel according to claim 4, wherein the first gate of the first TFT is disposed on the first active portion, and the second gate of the second TFT is disposed on the second active portion.

9. A display panel, comprising:
a substrate;
a first thin film transistor (TFT) disposed on the substrate and comprising a first active portion, a first source, and a first drain, the first source and the first drain disposed on the first active portion, wherein the first source is electrically connected to a first end of the first active portion, and the first drain is electrically connected to a second end of the first active portion; and
a pixel electrode layer disposed on the first TFT and electrically connected to the first drain;
wherein a material of the first drain comprises a transparent conductive material.

10. The display panel according to claim 9, wherein the first TFT further comprises a first gate disposed corresponding to the first active portion;
wherein the display panel further comprises:
a first planarization layer disposed between the first drain and the pixel electrode layer and comprising a first opening, wherein the pixel electrode layer is connected to the first drain through the first opening;
wherein the first opening is positioned corresponding to the first gate.

11. The display panel according to claim 10, further comprising:
an insulating layer disposed between the first source and the first drain which are arranged in different layers,
wherein a projection of the first source projected on the substrate at least partially overlaps with a projection of the first gate projected on the substrate.

12. The display panel according to claim 9, wherein the first source is made of a material same as the material of the first drain, and the first source and the first drain are disposed in a same layer.

13. The display panel according to claim 10, further comprising:
a passivation layer disposed on the pixel electrode layer, wherein a portion of the passivation layer, corresponding to the first opening, is provided with a second opening recessed downward;
a second planarization layer filled in the second opening, wherein an upper surface of the second planarization layer is flush with an upper surface of a portion of the passivation layer corresponding to the first planarization layer; and
a common electrode layer disposed on the passivation layer and the second planarization layer.

14. The display panel according to claim 10, further comprising:
a second thin film transistor (TFT) disposed on the substrate and comprising a second gate and a second active portion which are disposed in different layers and arranged corresponding to each other;
wherein the second TFT is electrically connected to the first TFT, a material of the first active portion of the first TFT comprises metal oxide, and a material of the second active portion of the second TFT comprises low-temperature polysilicon.

15. The display panel according to claim 14, further comprising:
a first light-shielding layer disposed between the substrate and the first active portion, wherein the first light-shielding layer is disposed corresponding to the first active portion and arranged in a same layer as the second gate.

16. The display panel according to claim 14, further comprising:
a second light-shielding layer comprising a first light-shielding portion and a second light-shielding portion disposed in a same layer;
wherein the first light-shielding portion is disposed corresponding to the first active portion and arranged between the substrate and the first TFT; and
wherein the second light-shielding portion is disposed corresponding to the second active portion and arranged between the substrate and the second TFT.

17. The display panel according to claim 15, wherein the second TFT further comprises a second source and a second drain which are arranged in a same layer;
the display panel further comprising:
a buffer layer disposed on the substrate, wherein the second gate is disposed on the buffer layer;
a first gate insulating layer disposed on the first active portion and the second gate insulating layer, wherein the first gate, the second source, and the second drain are disposed on the first gate insulating layer;
a second gate insulating layer disposed on the second gate, the first light-shielding layer, and the third gate insulating layer, wherein the first active portion is disposed on the second gate insulating layer;
a third gate insulating layer disposed on the second gate and the buffer layer, wherein the second gate and the first light-shielding layer are disposed on the third gate insulating layer;
an interlayer insulating layer disposed on the first gate, the second source, the second drain, and the first gate insulating layer, wherein the first source is disposed on the interlayer insulating layer; and
an insulating layer disposed on the first source and the interlayer insulating layer, wherein the first drain is disposed on the insulating layer.

18. The display panel according to claim 14, wherein the first gate of the first TFT is disposed on the first active portion, and the second gate of the second TFT is disposed on the second active portion.

19. The display panel according to claim 14, comprising a display part and a non-display part disposed on at least one side of the display part,
wherein the first TFT is included in the display part, and the second TFT is included in the non-display part.

20. An electronic terminal, comprising a display panel, the display panel comprising:
a substrate;
a first thin film transistor (TFT) disposed on the substrate and comprising a first active portion, a first source, and a first drain, the first source and the first drain disposed on the first active portion, wherein the first source is electrically connected to a first end of the first active portion, and the first drain is electrically connected to a second end of the first active portion; and
a pixel electrode layer disposed on the first TFT and electrically connected to the first drain,
wherein a material of the first drain comprises a transparent conductive material.
